(19) United States
(12) Patent Application Publication
(10) Pub. No.: US 2013/0135818 A1
(43) Pub. Date: May 30, 2013

(54) CONTAINER DATA CENTER AND METHOD FOR REDUCING NOISE IN THE CONTAINER DATA CENTER

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/332,485

(22) Filed: Dec. 21, 2011

(30) Foreign Application Priority Data
Nov. 25, 2011 (TW) 100143456

(51) Int. Cl. H05K 7/20

(52) U.S. Cl. 361/679.48

(57) ABSTRACT

A container data center includes a portable container, server cabinets, a decibel-meter, fans to cool the server cabinets, fan controlling systems to speed up or slow down the fans, an air conditioner to adjust a temperature inside the container, and a temperature adjustment system to receive a decibel level sensed by the decibel-meter. The temperature adjustment system compares the value of the received decibel level with a preset value. If the value of the received decibel level is greater than the preset value, the temperature adjustment system decreases the temperature of air outputted by the air conditioner, thereby the fan controlling systems slowing down the fans. If the value of the received decibel level is not greater than the preset value, the temperature adjustment system increases the temperature of the air outputted by the air conditioner, thereby the fan controlling systems speeding up the fans.

### BACKGROUND

1. Technical Field

The present disclosure generally relates to a container data center and a method for reducing noise in the container data center.

2. Description of Related Art

In a container data center, hundreds of servers may operate at the same time. When the servers are operating, the fans of the servers generate excessive noise. As a result, it is not comfortable for users working in the container data center.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIGS. 1 and 2 are schematic views of an exemplary embodiment of a container data center.

FIG. 3 is a block diagram of the container data center of FIG. 1.

FIG. 4 is a flowchart of an exemplary embodiment of a method for reducing noise in a container data center.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

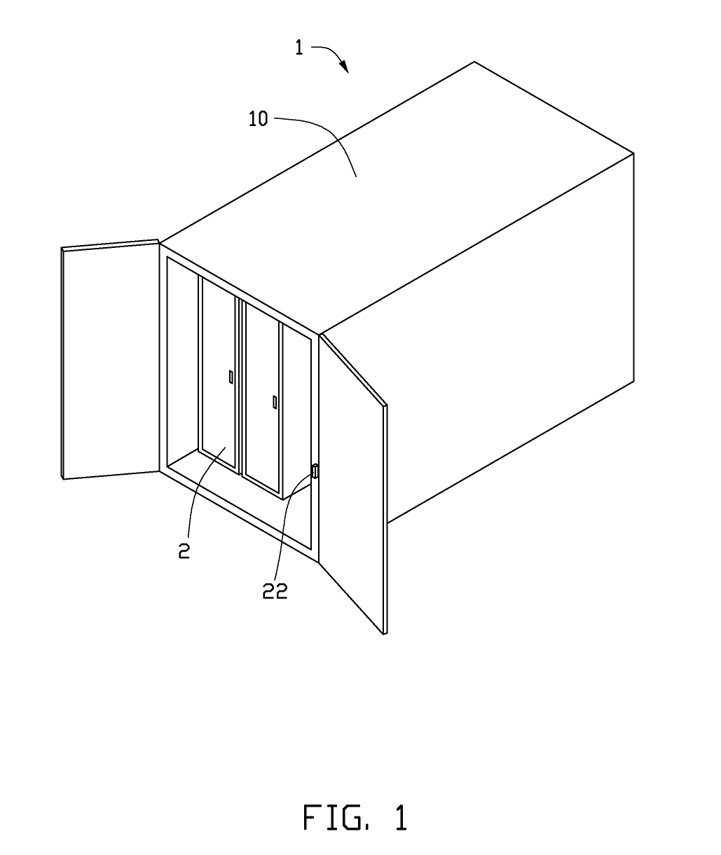

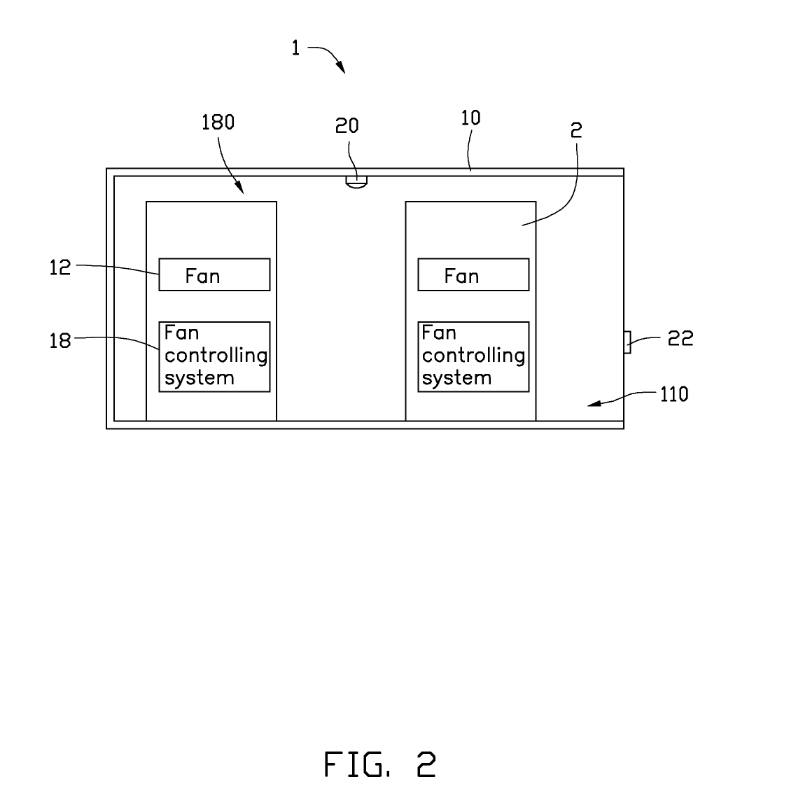

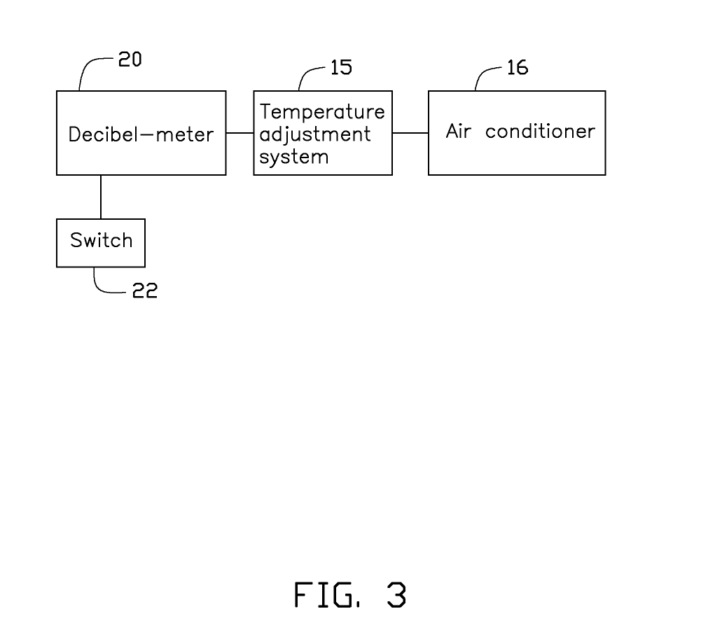

Referring to FIGS. 1-3, an exemplary embodiment of a container data center 1 includes a portable container 10, a plurality of server cabinets 2 accommodated in the container 10, a plurality of fans 12, a plurality of fan controlling systems 18, a temperature adjustment system 15, an air conditioner 16 connected to the temperature adjustment system 15, a decibel-meter 20 connected to the temperature adjustment system 15, and a switch 22 connected to the decibel-meter 20.

The container 10 includes a first region 110 for mounting the server cabinets 2 and a second region 180. Operators can pass through the second region 180 to check the server cabinets 2.

The fans 12 are set inside the server cabinets 2 to cool the server cabinets 2. The air conditioner 16 is set inside the container 10 to decrease the temperature inside the container 10. The temperature adjustment system 15 controls the air conditioner 16 to change the temperature inside the container 10. The fan controlling systems 18 control the fans 12 correspondingly. When the temperature of one of the server cabinets 2 is higher than a predetermined temperature, the fan controlling system 18 speeds up the corresponding fan 12. When the temperature of one of the server cabinets 2 is below the predetermined temperature, the fan controlling system 18 slows down the fan 12, thereby reducing the noise from the fan 12.

The decibel-meter 20 is set in the second region 180, such that decibel levels sensed by the decibel-meter 20 are those experience by operators in the second region 180. The switch 22 is set at an entrance of the container 10. When the switch 22 is on, the decibel-meter 20 is activated. When the switch 22 is off, the decibel-meter 20 is deactivated.

The temperature adjustment system 15 receives the decibel level sensed by the decibel-meter 20. When the decibel level received is greater than 60, the temperature adjustment system 15 can decrease the temperature of the air outputted by the air conditioner 16 in steps of about 0.5 degree Celsius increments to cool the container 10 to the predetermined temperature so that the fans can be slowed down and the decibel level reduced to comfortable level of 60 or less. When the decibel received is not greater than 60, namely the container 10 is not noisy, the temperature adjustment system 15 increases the temperature of the air outputted by the air conditioner 16 incrementally until balance is achieved between temperature and decibel level and thus save power consumed by the air container 16. In this embodiment, 60 decibels and 0.5 degree Celsius increment are merely examples of values presets by operators and can be other values.

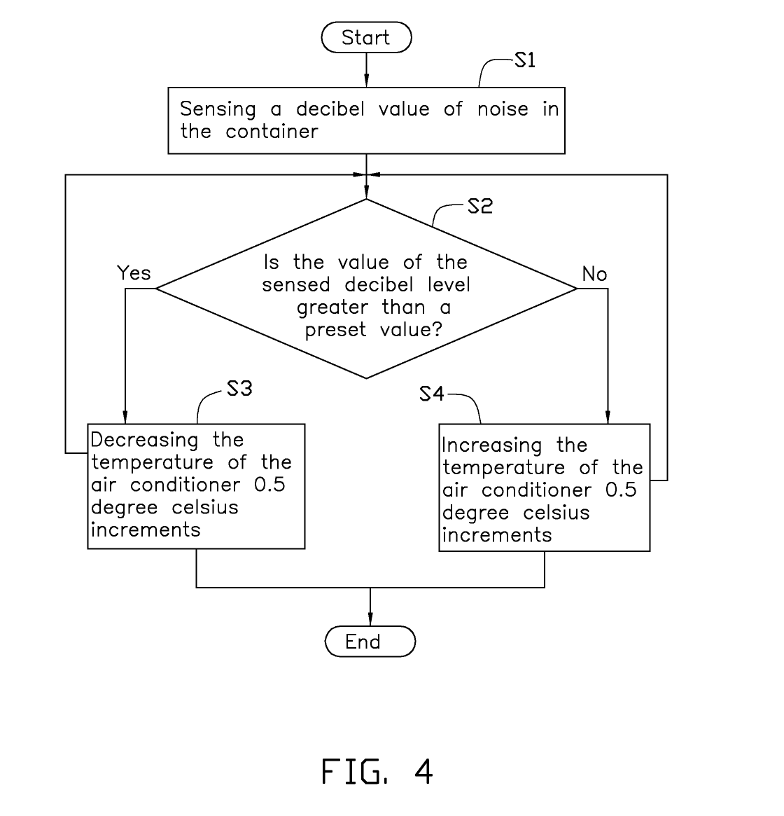

Referring to FIG. 4, an exemplary embodiment of a method for reducing noise in the container data center 1 includes the following steps.

In step S1, the decibel-meter 20 senses the noise in the container 10, and transmits the value of the sensed decibel to the temperature adjusting system 15.

In step S2, the temperature adjusting system 15 determines whether the value of the decibel level sensed by the decibel-meter 20 is greater than a preset value. If the value of the sensed decibel is greater than the preset value, the process flows to step S3. If the value of the sensed decibel level is not greater than the preset value, the process flows to step S4.

In step S3, the temperature adjustment system 15 decreases the temperature of the air outputted by the air conditioner 16 in steps of about 0.5 degree Celsius increments to cool the container 10 to the predetermined temperature so that the fans can be slowed down and the decibel level reduced to comfortable level of 60 or less. After that, the decibel-meter 20 further senses the noise inside the container 10, namely the process returns to step S2.

In step S4, the temperature adjustment system 15 increases the temperature of the air outputted by the air conditioner 16 in steps of about 0.5 degree Celsius increments for saving power consumed by the air container 16. In this condition, because the temperature in the container 10 is increased, the temperature in the server cabinet 2 is increased, too. As a result, the fan controlling system 18 speeds up the fan 12 to cool the server cabinet 2. After that, the decibel-meter 20 further senses the noise inside the container 10, namely the process returns to step S2.

The foregoing description of the exemplary embodiments of the disclosure has been presented only for the purposes of illustration and description and is not intended to be exhaustive or to limit the disclosure to the precise forms disclosed. Many modifications and variations are possible in light of everything above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A container data center comprising:
a portable container;
a plurality of server cabinets accommodated in the container;
a decibel-meter set inside the container to sense a decibel level of noise inside the container;
a plurality of fans set in the corresponding servers to cool the servers;
a plurality of fan controlling systems to speed up or slow down the corresponding fans;
an air conditioner to adjust a temperature inside the container; and
a temperature adjustment system to receive a decibel level sensed by the decibel-meter, and compare the value of the received decibel level with a preset value, wherein if the value of the received decibel level is greater than the preset value, the temperature adjustment system decreases the temperature of air outputted by the air conditioner, thereby the fan controlling systems slowing down the fans, if the value of the received decibel level is not greater than the preset value, the temperature adjustment system increases the temperature of air outputted by the air conditioner, thereby the fan controlling systems speeding up the fans.

2. The container data center of claim 1, further comprising a switch to activate or deactivate the decibel-meter.

3. The container data center of claim 2, wherein the switch is set at an entrance of the container.

4. The container data center of claim 1, wherein the preset value is 60, if the value of the received decibel level is greater than 60, the temperature adjustment system decreases the temperature of the air outputted by the air conditioner in steps of about 0.5 degree Celsius increments; if the value of the received decibel level is not greater than 60, the temperature adjustment system increases the temperature of the air outputted by the air conditioner in steps of about 0.5 degree Celsius increments.

5. A method for reducing noise in a container data center, the container data center comprising a portable container, a plurality of server cabinets accommodated in the container, a plurality of fans for cooling the servers, a plurality of fan controlling systems for speeding up or slowing down the corresponding fans, an air conditioner for cooling the container, and a temperature adjustment system for controlling the air conditioner, the method comprising:
sensing a decibel level of noise in the container, and transmitting the sensed decibel level to the temperature adjusting system;
determining whether the value of the sensed decibel level is greater than a preset value;
decreasing the temperature of air outputted by the air conditioner, thereby the fan controlling systems slowing down the fans, if the value of the received decibel level is greater than the preset value; and
increasing the temperature of the air outputted by the air conditioner, thereby the fan controlling systems speeding up the fans, if the value of the received decibel level is not greater than the preset value.

6. The method of claim 5, wherein the preset value is 60, if the value of the received decibel level is greater than 60, the temperature adjustment system deceases the temperature of the air conditioner in steps of about 0.5 degree Celsius increments; if the value of the received decibel level is not greater than 60, the temperature adjustment system increases the temperature of the air conditioner in steps of about 0.5 degree Celsius increments.
